(19) United States
(12) Patent Application Publication
(10) Pub. No.: US 2025/0372543 A1
(43) Pub. Date: Dec. 4, 2025

(54) PACKAGE COMPRISING A TRENCH CAPACITOR DEVICE WITH A METALLIZATION PORTION COMPRISING BAR METALLIZATION INTERCONNECTS

(71) Applicant: QUALCOMM Incorporated, San Diego, CA (US)

(72) Inventors: Aniket PATIL, San Diego, CA (US); Manuel ALDRETE, Encinitas, CA (US); Piyush GUPTA, San Diego, CA (US)

(21) Appl. No.: 18/680,875

(22) Filed: May 31, 2024

(51) Int. Cl. H01L 23/58; H01L 23/00; H01L 23/498; H01L 25/16

(52) U.S. Cl. CPC H01L 23/585; H01L 23/49816; H01L 25/16; H01L 24/16; H01L 2224/16225; H10D 1/716

(57) ABSTRACT

A package comprising a substrate; and a passive device coupled to the substrate through at least a first plurality of solder interconnects. The passive device comprises a trench capacitor device; an encapsulation layer; and a metallization portion coupled to the trench capacitor device and the encapsulation layer.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a substrate; and a passive device coupled to the substrate through at least a first plurality of solder interconnects. The passive device comprises a trench capacitor device; an encapsulation layer; and a metallization portion coupled to the trench capacitor device and the encapsulation layer.

Another example provides a passive device comprising a trench capacitor device; an encapsulation layer; and a metallization portion coupled to the trench capacitor device and the encapsulation layer.

Another example provides a method for fabricating a package. The method provides a substrate. The method couples a passive device to the substrate through at least a first plurality of solder interconnects. The passive device comprises a trench capacitor device; an encapsulation layer; and a metallization portion coupled to the trench capacitor device and the encapsulation layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate, a passive device with a metallization portion.

FIG. 2 illustrates an exemplary cross sectional profile view of a passive device with a metallization portion.

FIG. 3 illustrates an exemplary plan view of a passive device with a metallization portion.

FIG. 4 illustrates an exemplary plan view of a package that includes a substrate, a passive device with a metallization portion.

FIGS. 5A-5B illustrate an exemplary sequence for fabricating a passive device with a metallization portion.

FIG. 6 illustrates an exemplary flow chart of a method for fabricating a passive device with a metallization portion.

FIGS. 7A-7B illustrate an exemplary sequence for fabricating a package comprising a passive device with a metallization portion.

FIG. 8 illustrates an exemplary flow chart of a method for fabricating a package comprising a passive device with a metallization portion.

FIGS. 9A-9B illustrate an exemplary sequence for fabricating a metallization portion.

FIG. 10 illustrates an exemplary flow chart of a method for fabricating a metallization portion.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate; and a passive device coupled to the substrate through at least a first plurality of solder interconnects. The passive device comprises a trench capacitor device; an encapsulation layer; and a metallization portion coupled to the trench capacitor device and the encapsulation layer. The use of a passive device with a metallization portion helps provide a package that may be more compact and/or smaller, since underfill may no longer be required between the passive device and the substrate.

### Exemplary Package Comprising a Passive Device With a Metallization Portion

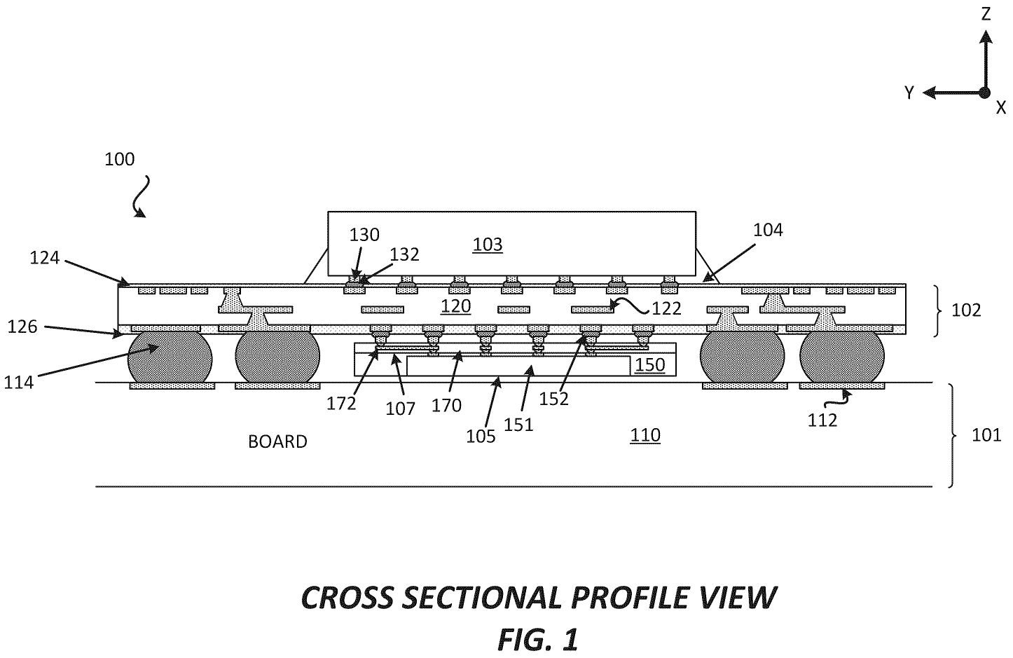

FIG. 1 illustrates a cross sectional profile view of a package 100 that includes a passive device with a metallization portion. The package 100 may be implemented as part of a package on package (POP). The package 100 is coupled to a board 101 through a plurality of solder interconnects 114. The board 101 includes at least one board dielectric layer 110 and a plurality of board interconnects 112. The board 101 may include a printed circuit board (PCB).

The package 100 includes a substrate 102, an integrated device 103, an underfill 104 and a passive device 105. The substrate 102 may be a package substrate. The substrate 102 includes a dielectric layer 120, a plurality of interconnects 122, a solder resist layer 124 and a solder resist layer 126. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The integrated device 103 may be coupled to a first surface (e.g., top surface) of the substrate 102. The underfill 104 is located between the integrated device 103 and the substrate 102. The underfill 104 may at least laterally surround the plurality of pillar interconnects 130 and/or the plurality of solder interconnects 132. The underfill 104 may be coupled to and touch a side wall of the integrated device 103. In some implementations, the underfill 104 may include a composite material comprising an epoxy polymer with filler. The substrate 102 is coupled to the board 101 through the plurality of solder interconnects 114.

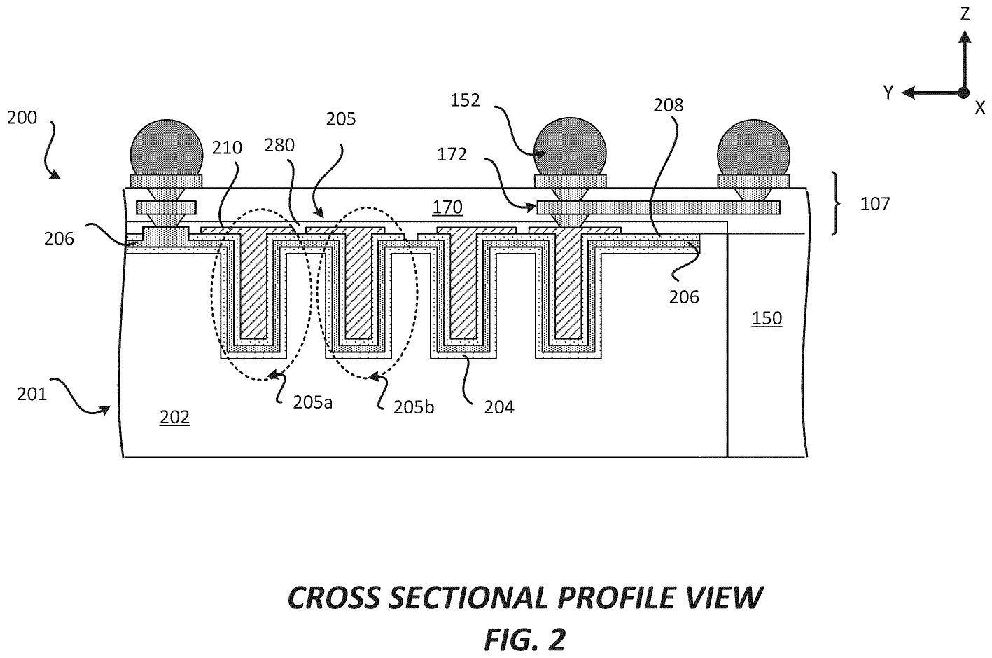

The passive device 105 includes a trench capacitor device 151, an encapsulation layer 150, and a metallization portion 107. The trench capacitor device 151 may include a plurality of trench capacitors. The metallization portion 107 comprises at least one dielectric layer 170 and a plurality of metallization interconnects 172. As will be further described below in FIG. 2, the plurality of metallization interconnects 172 may include at least one bar metallization interconnect. The at least one bar metallization interconnect may be bar pad metallization interconnect. The trench capacitor device 151 is coupled to the metallization portion 107. The encapsulation layer 150 is coupled to the trench capacitor device 151 and the metallization portion 107. The encapsulation layer 150 may at least partially encapsulate the trench capacitor device 151. The encapsulation layer 150 may include a mold, a resin, an epoxy and/or a filler. The encapsulation layer 150 may be different from the underfill 104. For example, the encapsulation layer 150 may include a different material and/or a different composition of material from the underfill 104. A more detailed example of a passive device with a metallization portion is illustrated and described below in FIG. 2.

The passive device 105 may be coupled to the substrate 102 through a plurality of solder interconnects 152. For example, the passive device 105 may be coupled to a second surface (e.g., bottom surface) of the substrate 102 through a plurality of solder interconnects 152. The plurality of solder interconnects 152 may be coupled to the metallization portion 107. For example, the plurality of solder interconnects 152 may be coupled to (i) metallization interconnects from the plurality of metallization interconnects 172 of the metallization portion 107 and (ii) interconnects from the plurality of interconnects 122 of the substrate 102. The plurality of solder interconnects 152 may be coupled to at least one bar metallization interconnects. The passive device 105 may be located laterally to the plurality of solder interconnects 114. A region located vertically between the passive device 105 and the substrate 102 may be free of an underfill. For example, a region located vertically between (i) the metallization portion 107 of the passive device 105 and (ii) the substrate 102 may be free of an underfill. The region between the substrate 102 and the passive device 105 may be free of an underfill because of the use of the metallization portion 107 and/or the at least one bar metallization interconnect allows for more solder interconnects to be coupled between the passive device 105 and the substrate 102. This may result in a stronger and more reliable mechanical coupling between the substrate 102 and the passive device 105, without the need of an underfill between the substrate 102 and the passive device 105. In addition, since additional space is no longer needed to accommodate the process of providing an underfill, the passive device 105 may be made bigger in size without increasing the size of the substrate 102 and/or decreasing the number of solder interconnects from the plurality of solder interconnects 114. Alternatively, the size of the substrate 102 may be reduced while still accommodating the passive device 105. Moreover, the metallization portion 107 may allow for more electrical paths between the substrate 102 and the passive device 105, which can help to improve the performance of the power distribution network for the package.

FIG. 2 illustrates a cross sectional profile view of a passive device 200 that is configured to operate as a trench capacitor device (e.g., deep trench capacitor device). The passive device 200 may be a chiplet. The passive device 200 may represent any of the passive devices described in the disclosure, such as the passive device 105. The passive device 200 may be an integrated passive device (e.g., silicon passive device) that includes multiple trench capacitors (e.g., deep trench capacitors). The passive device 200 may be a means for trench capacitance. The passive device 200 includes a front side and a back side. The front side of the passive device 200 may include the plurality of trench capacitors. The front side of the passive device 200 may include a metallization portion. The back side of the passive device 200 may include the side that includes a die substrate.

The passive device 200 include a trench capacitor device 201, a metallization portion 107 and an encapsulation layer 150. The trench capacitor device 201 is coupled to the metallization portion 107. The encapsulation layer 150 is coupled to the trench capacitor device 201 and the metallization portion 107. The encapsulation layer 150 may at least partially encapsulate the trench capacitor device 201.

The trench capacitor device 201 includes a passive device substrate 202 (e.g., chiplet substrate) and a plurality of trench capacitors 205. The passive device substrate 202 may include silicon (Si). The passive device substrate 202 may include a plurality of trenches and/or cavities over which capacitors may be formed.

The plurality of trench capacitors 205 includes a trench capacitor 205a and a trench capacitor 205b. The trench capacitor 205a and the trench capacitor 205b may be configured to be part of a same capacitor (e.g., first capacitor, first trench capacitor). The trench capacitor 205a (e.g., first trench capacitor) and the trench capacitor 205b (e.g., second trench capacitor) may be configured to be part of separate circuits. The trench capacitor 205a and the trench capacitor 205b may be configured to be coupled to and/or part of a first power distribution network (PDN). The trench capacitor 205a and the trench capacitor 205b may be configured to be part of a first electrical path for a first power for a package. The trench capacitor 205a and the trench capacitor 205b may be configured to be electrically coupled to integrated device(s). In some implementations, a first trench capacitor may be configured to be coupled to a first power (e.g., Vdd1). In some implementations, a second trench capacitor may be configured to be coupled to a second power (e.g., Vdd2). In some implementations, a third trench capacitor may be configured to be coupled to a third power (e.g., Vdd3). In some implementations, the trench capacitor device 201 may be configured to be coupled to ground (e.g., Vss). Different implementations may be configured to power (e.g., Vdd) and ground (e.g., Vss) differently.

As shown in FIG. 2, the trench capacitor device 201 includes the passive device substrate 202, an oxide layer 204, a first electrically conductive layer 206, a dielectric layer 208, a second electrically conductive layer 210 and a dielectric layer 280. The first electrically conductive layer 206 and/or the second electrically conductive layer 210 may include polysilicon. The oxide layer 204 and/or the dielectric layer 208 may include SiO₂ (e.g., low-pressure chemical vapor deposition (LPCVD) SiO₂) or Si₃N₄ (e.g., LPCVD Si₃N₄). Portions of the oxide layer 204, the first electrically conductive layer 206, the dielectric layer 208, and the second electrically conductive layer 210 may be located in trenches and/or cavities of the passive device substrate 202. It is noted that a passive device substrate 202 may be considered to have a trench or a cavity, even if the trench or the cavity is filled with one or more materials.

The trench capacitor 205a (e.g., first trench capacitor, first capacitor, means for first trench capacitance) may be defined by (i) a first portion of the oxide layer 204, (ii) a first portion of the first electrically conductive layer 206, (iii) a first portion of the dielectric layer 208, and (iv) a first portion of the second electrically conductive layer 210 that are located in a trench (e.g., first trench) of the passive device substrate 202.

The trench capacitor 205b (e.g., second trench capacitor, second capacitor, means for second trench capacitance) may be defined by (i) a second portion of the oxide layer 204, (ii) a second portion of the first electrically conductive layer 206, (iii) a second portion of the dielectric layer 208, and (iv) a second portion of the second electrically conductive layer 210 that are located in a trench (e.g., second trench) of the passive device substrate 202. It is noted that trench capacitor 205b may be part of a same capacitor as the trench capacitor 205a. That is, the trench capacitor 205a and the trench capacitor 205b may be configured to be electrically coupled together to form a capacitor (e.g., first capacitor) with a greater capacitance. The back side of the trench capacitor device 201 may be the side that includes the passive device substrate 102. The back side of the passive device 200 may be the side that includes the passive device substrate 102.

The metallization portion 107 includes at least one dielectric layer 120 and a plurality of metallization interconnects 172. The plurality of metallization interconnects 172 may include at least one bar metallization interconnect. The metallization portion 107 is coupled to the front side of the trench capacitor device 201. The plurality of metallization interconnects 172 are coupled to the first electrically conductive layer 206. The plurality of metallization interconnects 172 may be configured to be electrically coupled to the plurality of trench capacitors 205. The plurality of solder interconnects 152 may be coupled to the plurality of metallization interconnects 172.

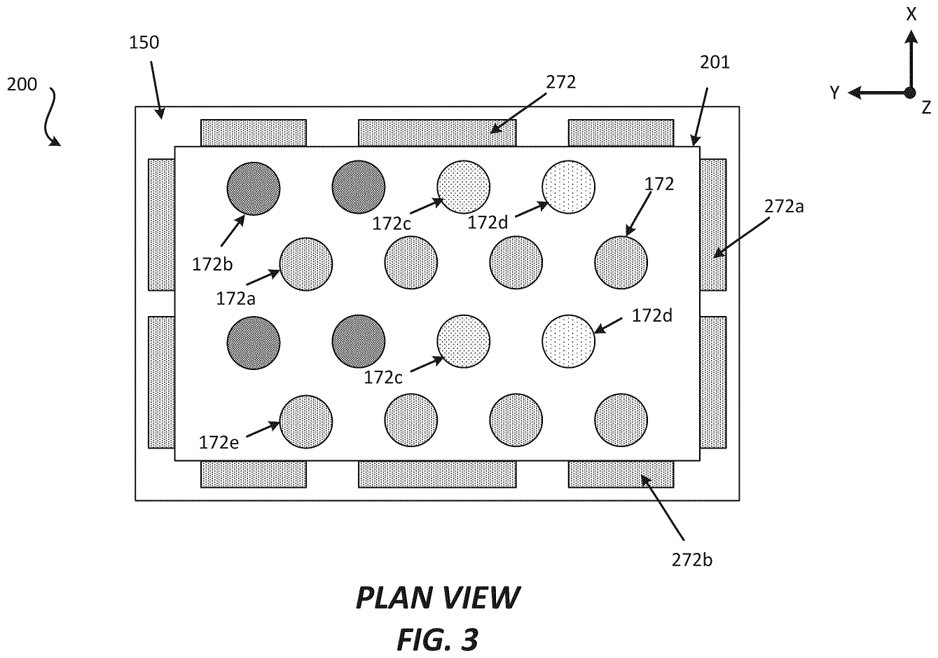

FIG. 3 illustrates a plan view of the passive device 200. The passive device 200 includes the trench capacitor device 201 and the metallization portion 107. The metallization portion 107 includes a plurality of metallization interconnects 172. The plurality of metallization interconnects 172 may include a plurality of bar metallization interconnects 272. A bar metallization interconnect may be an interconnect that has the shape of an elongated interconnect, such as a brick shaped interconnect. A bar metallization interconnect may be a rail metallization interconnect. It is noted that a bar metallization interconnect may have different shapes, dimensions and/or sizes. The plurality of bar metallization interconnects 272 include a first bar metallization interconnect 272a and a second bar metallization interconnect 272b. A plurality of bar metallization interconnects 272 (including the first bar metallization interconnect 272a and the second bar metallization interconnect 272b) may be located along a periphery of the passive device 200 (e.g., along periphery and/or edges of trench capacitor device 201). The plurality of bar metallization interconnects 272 may form one or more walls (e.g., segmented walls) along a periphery of the passive device 200 (e.g., along periphery and/or edges of trench capacitor device 201). The plurality of bar metallization interconnects may be located along the edge(s) of the trench capacitor device 151. A bar metallization interconnect may be a metallization interconnect that has a length (L) and a width (W), where the length is at least 2 times longer than the width. In some implementations, a bar metallization interconnect is coupled to and touching a solder interconnect. Some solder interconnects from the plurality of solder interconnects 152 may be configured to be electrically coupled to ground. Some solder interconnects from the plurality of solder interconnects 152 may be configured to be electrically coupled to power.

The plurality of metallization interconnects 172 may include a plurality of metallization interconnects 172a, a plurality of metallization interconnects 172b, a plurality of metallization interconnects 172c, a plurality of metallization interconnects 172d and a plurality of metallization interconnects 172e. A plurality of solder interconnects 152 may be coupled to the plurality of metallization interconnects 172a, the plurality of metallization interconnects 172b, the plurality of metallization interconnects 172c, the plurality of metallization interconnects 172d and/or the plurality of metallization interconnects 172e. In some implementations, the plurality of metallization interconnects 172a are configured to provide at least one electrical path for ground and/or Vss. The plurality of metallization interconnects 172a may be a rail of metallization interconnects. In some implementations, the plurality of metallization interconnects 172c are configured to provide at least one electrical path for ground and/or Vss. The plurality of metallization interconnects 172a may be a rail of metallization interconnects. In some implementations, the plurality of metallization interconnects 172b are configured to provide at least one electrical path for a first power and/or Vldd. In some implementations, the plurality of metallization interconnects 172c are configured to provide at least one electrical path for a second power and/or V2dd. In some implementations, the plurality of metallization interconnects 172d are configured to provide at least one electrical path for a third power and/or V3dd. The use of the metallization portion 107 allows for more electrical paths for different power lines.

The plurality of bar metallization interconnects 272 may be configured to operate as an electromagnetic interference (EMI) shield. The plurality of bar metallization interconnects 272 may be configured to be electrically coupled to ground and/or Vss. In some implementations, the plurality of bar metallization interconnects 272 may be configured to be electrically coupled to power and/or Vdd. In some implementations, the first bar metallization interconnect 272a may be configured to be electrically coupled to ground, and the second bar metallization interconnect 272b may be configured to be electrically coupled to power. A plurality of solder interconnects 152 may be coupled to the plurality of bar metallization interconnects 272. In addition, the plurality of bar metallization interconnects 272 and the plurality of solder interconnects 152 help provide a robust mechanical coupling between the passive device 200 and a substrate. This, in turn means that an underfill is no longer needed between the passive device 200 and the substrate. Since an underfill is no longer needed, the spacing between an edge of the passive device 200 and a solder interconnect can be minimized without having to account for space to provide an underfill. With smaller spacing requirements, the lateral size of the substrate may be reduced, while maintaining and/or improving the performance of the package and/or the integrated device. The design of the passive device may also help with the overall performance of the power distribution network of the package, which will help with the performance of the integrated device and/or the package.

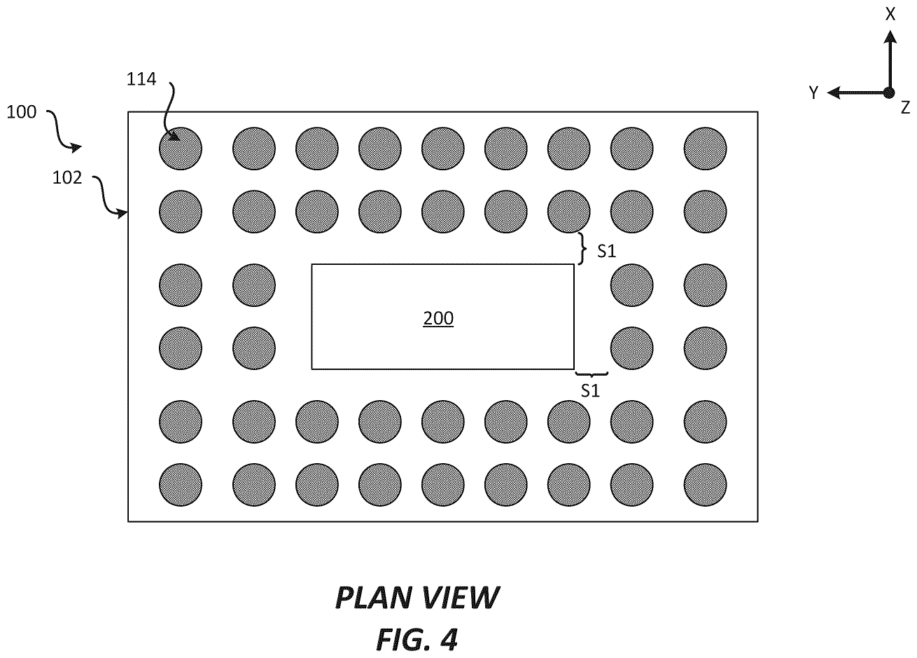

FIG. 4 illustrates a plan view of the package 100 that includes the substrate 102, the passive device 200 and the plurality of solder interconnects 114. FIG. 4 illustrates that a space (S1) between an edge of the passive device 200 and a nearest solder interconnect from the plurality of solder interconnects 114. In some implementations, the space (e.g., minimum space) between one or more edges of the passive device 200 and a nearest solder interconnect from the plurality of solder interconnects 114 is about 280 micrometers. In some implementations, the space (e.g., minimum space) between one or more edges of the passive device 200 and a nearest solder interconnect from the plurality of solder interconnects 114 is less than 500 micrometers. In some implementations, the space (e.g., minimum space) between each edge of the passive device 200 and a nearest solder interconnect from the plurality of solder interconnects 114 is less than 500 micrometers. This is possible because extra space is not required to accommodate for the process of providing an underfill between the passive device 200 and the substrate 102. This allows bigger passive devices to be coupled to the substrate without having to remove solder interconnects from the plurality of solder interconnects 114 and/or increasing the lateral size of the substrate 102.

An integrated device (e.g., 103) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Passive Device With a Metallization Portion

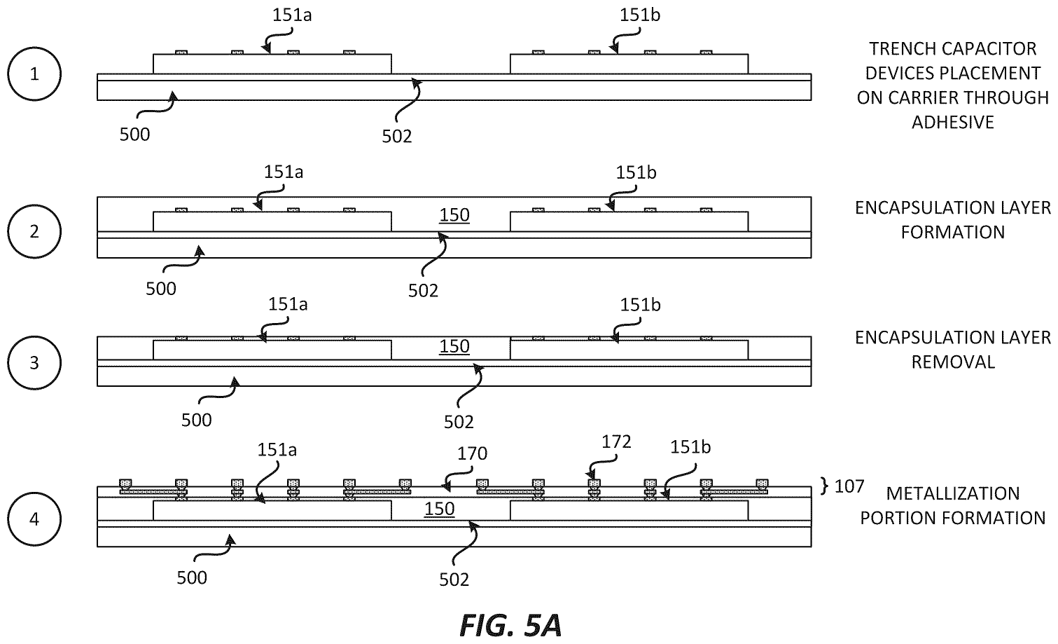

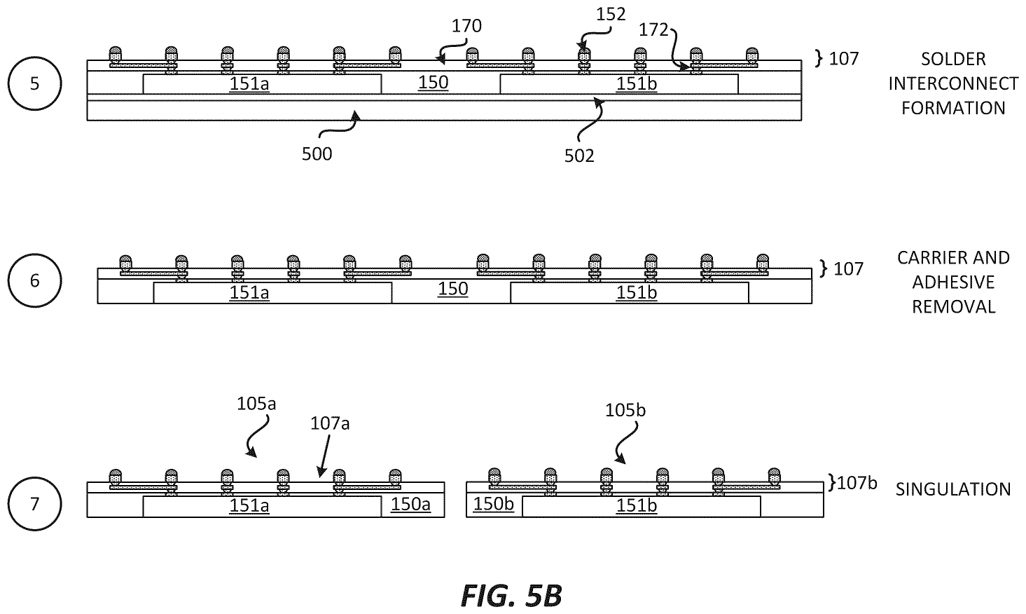

In some implementations, fabricating a passive device includes several processes. FIGS. 5A-5B illustrate an exemplary sequence for providing or fabricating a passive device. In some implementations, the sequence of FIGS. 5A-5B may be used to provide or fabricate the passive device 105. However, the process of FIGS. 5A-5B may be used to fabricate any of the passive devices described in the disclosure.

It should be noted that the sequence of FIGS. 5A-5B may combine one or more stages in order to simplify and/or clarify the sequence for providing or fabricating a passive device. In some implementations, the order of the processes may be changed or modified. In some implementations, one or more of processes may be replaced or substituted without departing from the scope of the disclosure.

Stage 1, as shown in FIG. 5A, illustrates a state after a trench capacitor device 151a and a trench capacitor device 151b are placed and coupled to a carrier 500 through an adhesive 502. The back side of the trench capacitor devices may be coupled to the carrier 500 through the adhesive 502. The carrier 500 may be a glass carrier. Each of the trench capacitor devices may include a die substrate and a plurality of trench capacitors (e.g., deep trench capacitors).

Stage 2 illustrates a state after an encapsulation layer 150 is formed and coupled to the trench capacitor device 151a, the trench capacitor device 151b, the adhesive 502 and/or the carrier 500. The encapsulation layer 150 may include a mold, a resin and/or an epoxy. The encapsulation layer 150 may be a means for encapsulation. The encapsulation layer 150 may be provided by using a compression and transfer molding process, a sheet molding process, or a liquid molding process. The encapsulation layer 150 may be over molded, and formed over the trench capacitor device 151a and the trench capacitor device 151b.

Stage 3 illustrates a state after portions of the encapsulation layer 150 are removed. A grinding process and/or a polishing process may be used to remove portions of the encapsulation layer 150.

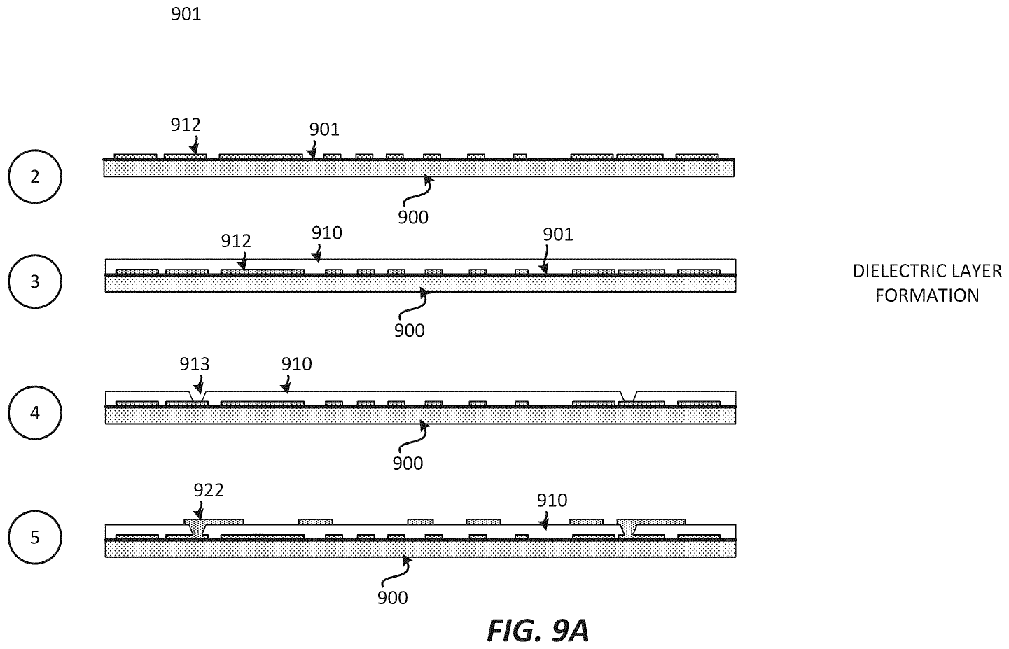

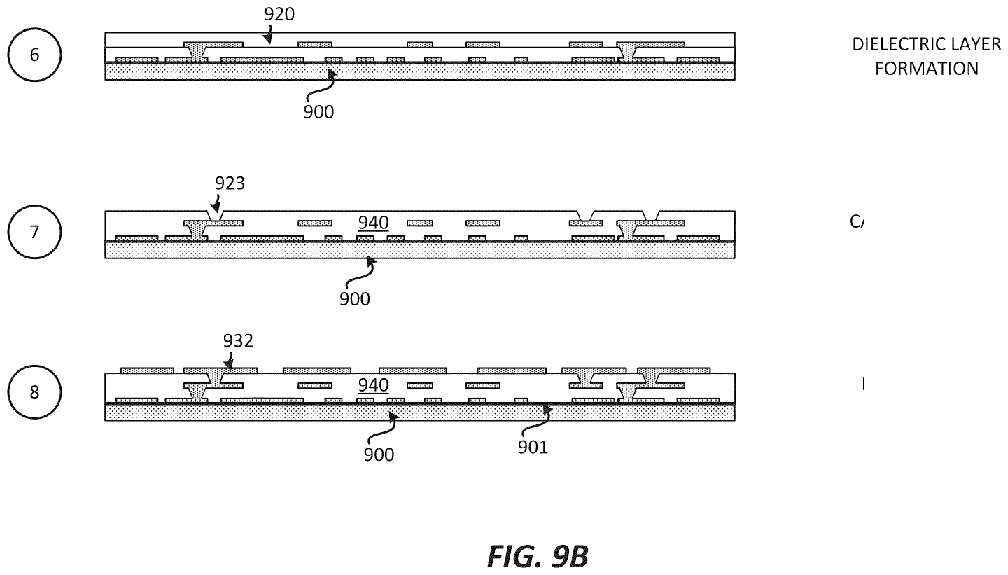

Stage 4, illustrates a state after a metallization portion 107 is formed and coupled to the trench capacitor(s) (e.g., 151a, 151b) and the encapsulation layer 150. The metallization portion 107 may include at least one dielectric layer 120 and a plurality of metallization interconnects 172. The plurality of metallization interconnects 172 may include a plurality of bar metallization interconnects. FIGS. 9A-9B illustrates an example of forming a metallization portion.

Stage 5 of FIG. 5B, illustrates a state after a plurality of solder interconnects 152 are coupled to the plurality of metallization interconnects 172. A solder reflow process may be used to couple the plurality of solder interconnects 152 to the plurality of metallization interconnects 172.

Stage 6 illustrates a state after the encapsulation layer 150, and the trench capacitor devices are decoupled (e.g., de-bonded) from carrier 500 and the adhesive 502.

Stage 7 illustrates a state after singulation through the encapsulation layer 150 and the metallization portion 107, resulting in a passive device 105a and a passive device 105b. A sawing process may be used to singulate. Stage 7 illustrates an example of (i) a passive device 105a that includes a trench capacitor device 151a, an encapsulation layer 150a and a metallization portion 107a, where the metallization portion 107a may include a bar metallization interconnect, and (ii) a passive device 105b that includes a trench capacitor device 151b, an encapsulation layer 150b and a metallization portion 107b, where the metallization portion 107b may include a bar metallization interconnect.

### Exemplary Flow Diagram of a Method for Fabricating a Passive Device With a Metallization Portion

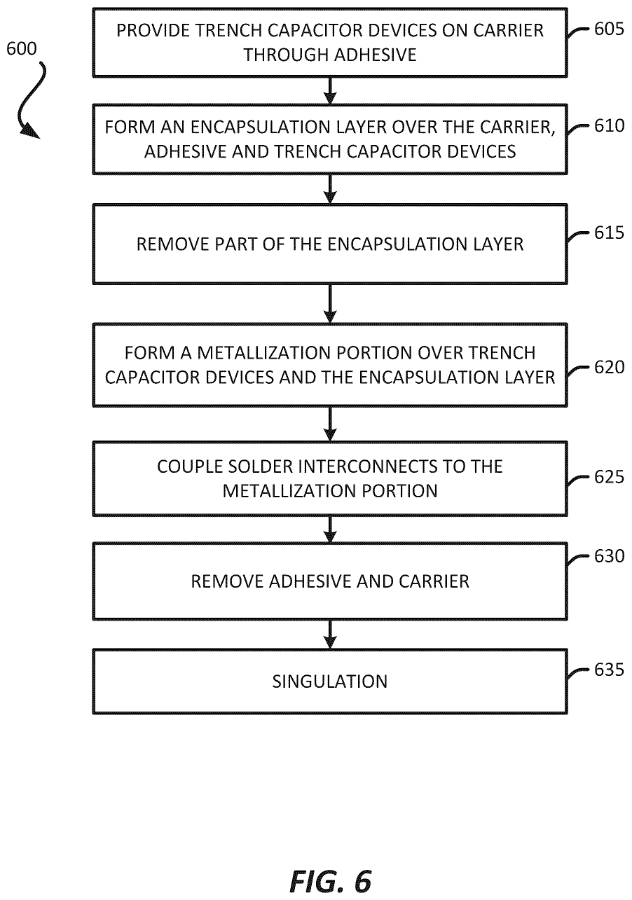

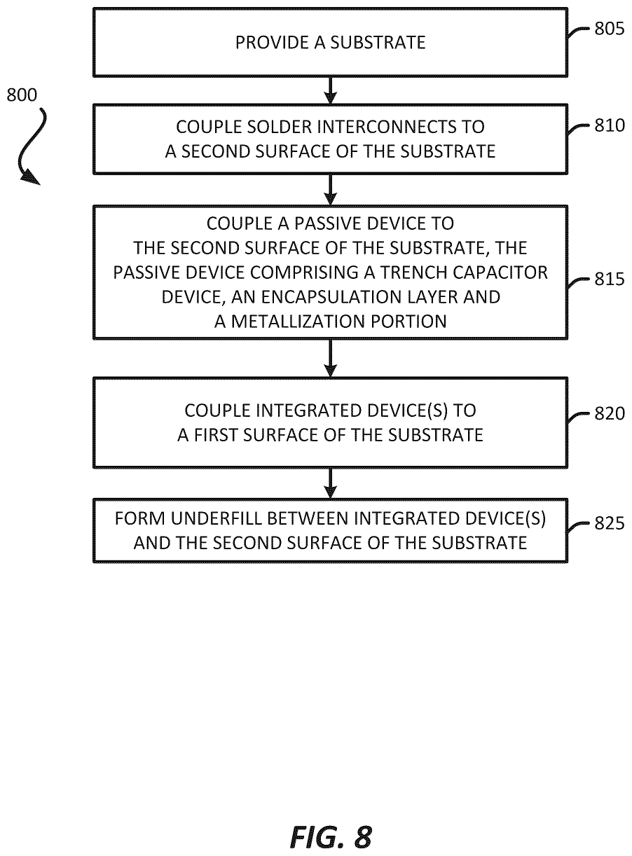

In some implementations, fabricating a passive device includes several processes. FIG. 8 illustrates an exemplary flow diagram of a method 600 for providing or fabricating a passive device. In some implementations, the method 600 of FIG. 6 may be used to provide or fabricate the passive device 105 described in the disclosure. However, the method 600 may be used to provide or fabricate any of the passive devices described in the disclosure.

It should be noted that the method 600 of FIG. 6 may combine one or more processes in order to simplify and/or clarify the method for providing or fabricating a passive device. In some implementations, the order of the processes may be changed or modified.

The method provides (at 605) a plurality of trench capacitor devices on a carrier through an adhesive. Stage 1 FIG. 5A, illustrates and describes an example of a state after a trench capacitor device 151a and a trench capacitor device 151b are placed and coupled to a carrier 500 through an adhesive 502. The back side of the trench capacitor devices may be coupled to the carrier 500 through the adhesive 502. The carrier 500 may be a glass carrier. Each of the trench capacitor devices may include a die substrate and a plurality of trench capacitors (e.g., deep trench capacitors).

The method forms (at 610) an encapsulation layer over the carrier, the adhesive and the plurality of trench capacitor devices. Stage 2 of FIG. 5A, illustrates and describes an example of a state after an encapsulation layer 150 is formed and coupled to the trench capacitor device 151a, the trench capacitor device 151b, the adhesive 502 and/or the carrier 500. The encapsulation layer 150 may include a mold, a resin and/or an epoxy. The encapsulation layer 150 may be a means for encapsulation. The encapsulation layer 150 may be provided by using a compression and transfer molding process, a sheet molding process, or a liquid molding process. The encapsulation layer 150 may be over molded, and formed over the trench capacitor device 151a and the trench capacitor device 151b.

The method removes (at 615) part of the encapsulation layer. Stage 3 of FIG. 5A, illustrates and describes an example of a state after portions of the encapsulation layer 150 are removed. A grinding process and/or a polishing process may be used to remove portions of the encapsulation layer 150.

The method forms (at 620) a metallization portion over the plurality of trench capacitor devices and the encapsulation layer. Stage 4 of FIG. 5A, illustrates and describes an example of a state after a metallization portion 107 is formed and coupled to the trench capacitor(s) (e.g., 151a, 151b) and the encapsulation layer 150. The metallization portion 107 may include at least one dielectric layer 120 and a plurality of metallization interconnects 172. The plurality of metallization interconnects 172 may include a plurality of bar metallization interconnects. FIGS. 9A-9B illustrates an example of forming a metallization portion.

The method couples (at 625) a plurality of solder interconnects to the plurality of metallization interconnects of the metallization portion. Stage 5 of FIG. 5B, illustrates and describes an example of a state after a plurality of solder interconnects 152 are coupled to the plurality of metallization interconnects 172. A solder reflow process may be used to couple the plurality of solder interconnects 152 to the plurality of metallization interconnects 172.

The method removes (at 630) the carrier and the adhesive from the encapsulation layer and the plurality of trench capacitor devices. Stage 6 of FIG. 5B, illustrates and describes an example of a state after the encapsulation layer 150, and the trench capacitor devices are decoupled (e.g., de-bonded) from carrier 500 and the adhesive 502.

The method performs (at 635) singulation. Stage 7 of FIG. 5B, illustrates and describes an example of a state after singulation through the encapsulation layer 150 and the metallization portion 107, resulting in a passive device 105a and a passive device 105b. A sawing process may be used to singulate. Stage 7 illustrates an example of (i) a passive device 105a that includes a trench capacitor device 151a, an encapsulation layer 150a and a metallization portion 107a, where the metallization portion 107a may include a bar metallization interconnect, and (ii) a passive device 105b that includes a trench capacitor device 151b, an encapsulation layer 150b and a metallization portion 107b, where the metallization portion 107b may include a bar metallization interconnect.

### Exemplary Sequence for Fabricating a Package

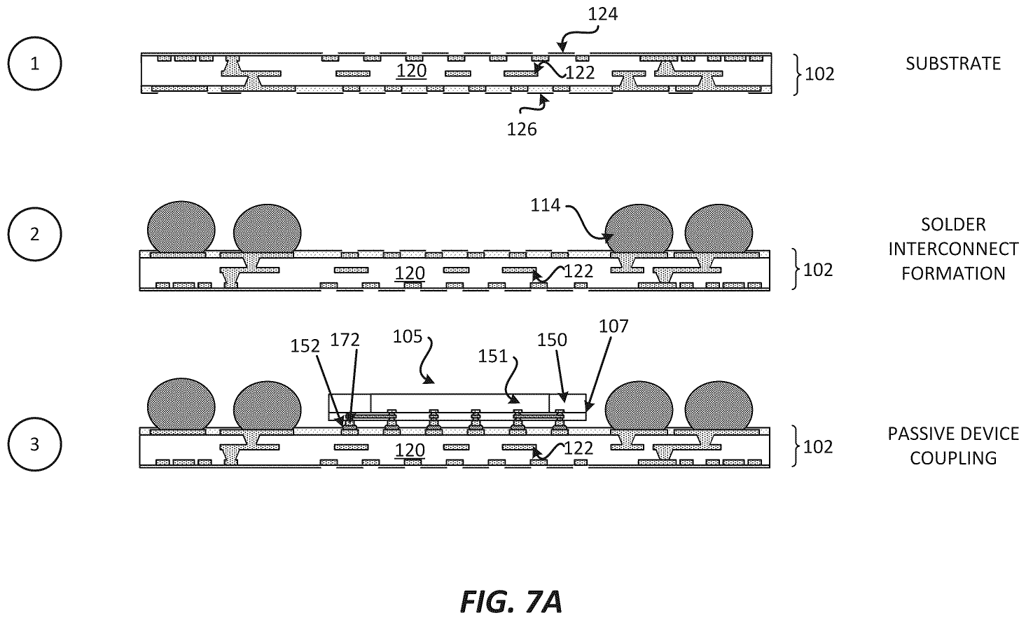

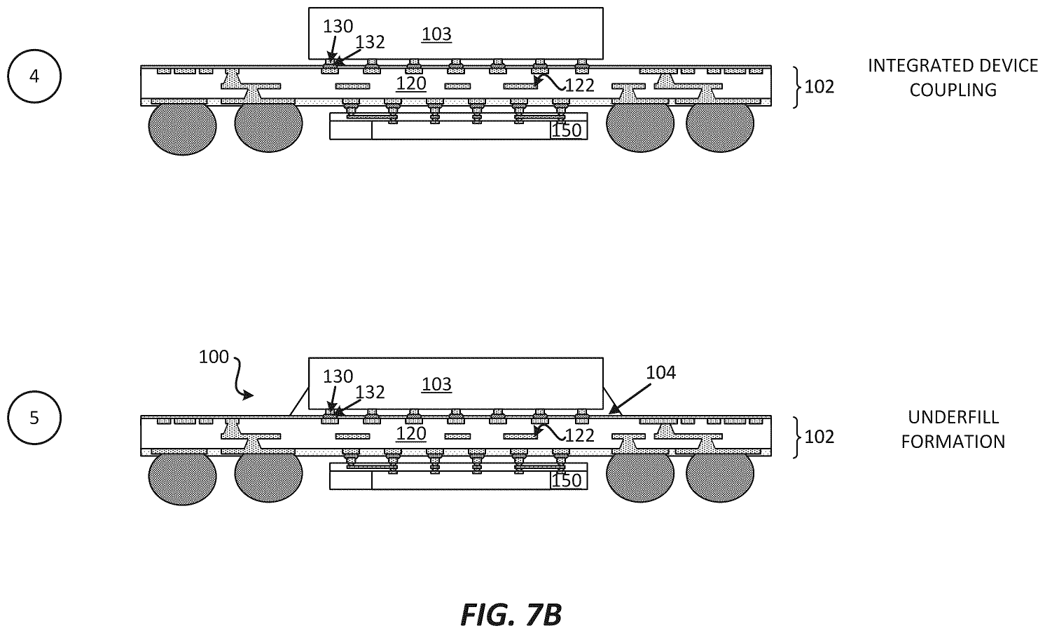

In some implementations, fabricating a package includes several processes. FIGS. 7A-7B illustrate an exemplary sequence for providing or fabricating a package. In some implementations, the sequence of FIGS. 7A-7B may be used to provide or fabricate the package 100. However, the process of FIGS. 7A-7B may be used to fabricate any of the packages described in the disclosure.

It should be noted that the sequence of FIGS. 7A-7B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 7A, illustrates a state after a substrate 102 is provided. The substrate 102 may be a first substrate. The substrate 102 includes at least one dielectric layer 120 and a plurality of interconnects 122. The substrate 102 may include a first surface (e.g., top surface) and a second surface (e.g., bottom surface). The substrate 102 may include solder resist layers. (e.g., 124, 126) The substrate 102 may be fabricated using the method as described in FIGS. 9A-9B.

Stage 2 illustrates a state after a plurality of solder interconnects 114 are coupled to the second surface of the substrate 102. A solder reflow process may be used to couple the plurality of solder interconnects 114 to the substrate 102.

Stage 3 illustrates a state after a passive device 105 is coupled to the second surface of the substrate 102. The passive device 105 may include a trench capacitor device 151, a metallization portion 107 and an encapsulation layer 150. The front side of the passive device 105 may be coupled to the substrate 102 through a plurality of solder interconnects 152. A solder reflow process may be used to couple the passive device 105 to the substrate 102. The plurality of solder interconnects 152 may be coupled to the substrate 102 and the metallization portion 107. For example, in some implementations, the plurality of solder interconnects 152 may be coupled to (i) the plurality of interconnects 122 of the substrate 102 and (ii) the plurality of metallization interconnects 172 of the metallization portion 107.

Stage 4, as shown in FIG. 7B, illustrates a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

Stage 5 illustrates a state after an underfill 104 is formed, dispensed and/or provided. The underfill 104 may be located vertically between the integrated device 103 and the substrate 102. A flow process may be used to provide the underfill 104. Stage 5 may illustrates an example of the package 100.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package

In some implementations, fabricating a package includes several processes. FIG. 8 illustrates an exemplary flow diagram of a method 800 for providing or fabricating a package. In some implementations, the method 800 of FIG. 8 may be used to provide or fabricate the package 100 described in the disclosure. However, the method 800 may be used to provide or fabricate any of the packages described in the disclosure.

It should be noted that the method 800 of FIG. 8 may combine one or more processes in order to simplify and/or clarify the method for providing or fabricating a package. In some implementations, the order of the processes may be changed or modified.

The method provides (at 805) a substrate. Stage 1 of FIG. 7A, illustrates and describes an example of a state after a substrate 102 is provided. The substrate 102 may be a first substrate. The substrate 102 includes at least one dielectric layer 120 and a plurality of interconnects 122. The substrate 102 may include a first surface (e.g., top surface) and a second surface (e.g., bottom surface). The substrate 102 may include solder resist layers. (e.g., 124, 126) The substrate 102 may be fabricated using the method as described in FIGS. 9A-9B.

The method couples (at 810) a plurality of solder interconnects to a second surface of the substrate. Stage 2 of FIG. 7A, illustrates and describes an example of a state after a plurality of solder interconnects 114 are coupled to the second surface of the substrate 102. A solder reflow process may be used to couple the plurality of solder interconnects 114 to the substrate 102.

The method couples (at 815) a passive device to the second surface of the substrate. The passive device may include a trench capacitor device, an encapsulation layer and a metallization portion. Stage 3 of FIG. 7A, illustrates and describes an example of a state after a passive device 105 is coupled to the second surface of the substrate 102. The passive device 105 may include a trench capacitor device 151, a metallization portion 107 and an encapsulation layer 150. The front side of the passive device 105 may be coupled to the substrate 102 through a plurality of solder interconnects 152. A solder reflow process may be used to couple the passive device 105 to the substrate 102. The plurality of solder interconnects 152 may be coupled to the substrate 102 and the metallization portion 107. For example, in some implementations, the plurality of solder interconnects 152 may be coupled to (i) the plurality of interconnects 122 of the substrate 102 and (ii) the plurality of metallization interconnects 172 of the metallization portion 107.

The method couples (at 820) an integrated device to a first surface of the substrate. Stage 4 of FIG. 7B, illustrates and describes an example of a state after an integrated device 103 is coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. A solder reflow process may be used to couple the integrated device 103 to the substrate 102.

The method forms (at 825) an underfill between the integrated device and the first surface of the substrate. Stage 5 of FIG. 7B, illustrates and describes an example of a state after an underfill 104 is formed, dispensed and/or provided. The underfill 104 may be located vertically between the integrated device 103 and the substrate 102. A flow process may be used to provide the underfill 104. Stage 5 may illustrates an example of the package 100.

### Exemplary Sequence for Fabricating a Metallization Portion

In some implementations, fabricating a metallization portion includes several processes. FIGS. 9A-9B illustrate an exemplary sequence for providing or fabricating a metallization portion. In some implementations, the sequence of FIGS. 9A-9B may be used to provide or fabricate the metallization portion 107. However, the process of FIGS. 9A-9B may be used to fabricate any of the metallization portions described in the disclosure. In some implementations, the sequence of FIGS. 9A-9B may be used to fabricate a substrate.

It should be noted that the sequence of FIGS. 9A-9B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 may be located over the carrier 900. The carrier 900 may be replaced with other components and/or materials.

Stage 2 illustrates a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of metallization interconnects 123.

Stage 3 illustrates a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

Stage 4 illustrates a state after a plurality of cavities 913 is formed in the dielectric layer 910. The plurality of cavities 913 may be formed using an etching process (e.g., photo etching process), a laser process, an exposure process and/or a development process.

Stage 5 illustrates a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

Stage 6, as shown in FIG. 9B, illustrates a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 7, illustrates a state after a plurality of cavities 923 is formed in the dielectric layer 940. The dielectric layer 940 may represent the dielectric layer 910 and/or the dielectric layer 920. The plurality of cavities 923 may be formed using an etching process (e.g., photo etching process), a laser process, an exposure process and/or a development process.

Stage 8 illustrates a state after interconnects 932 are formed in and over the dielectric layer 940, including in and over the plurality of cavities 923. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

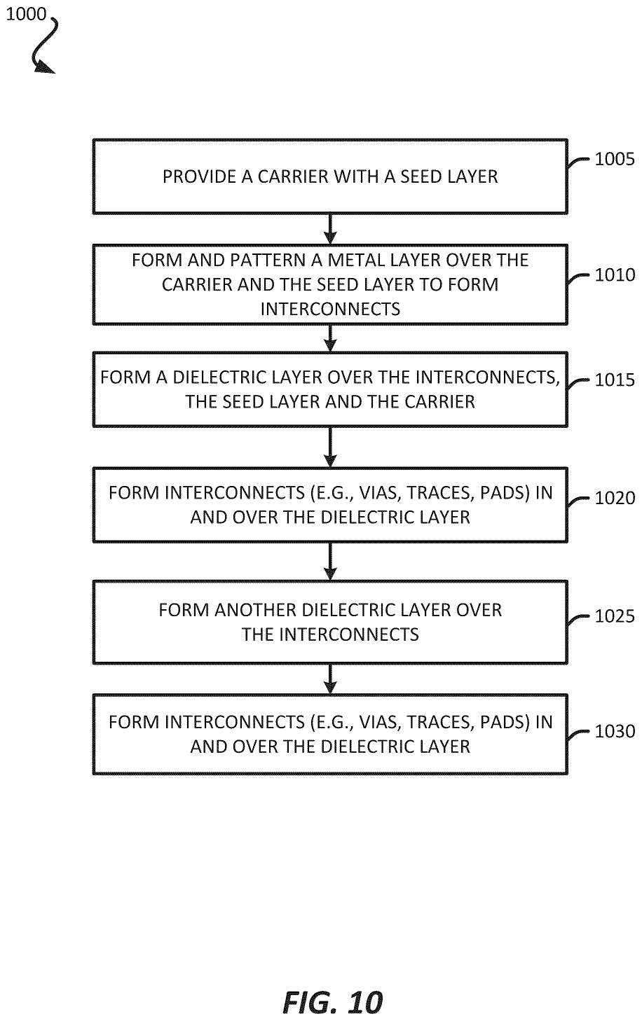

In some implementations, fabricating a metallization portion includes several processes. FIG. 10 illustrates an exemplary flow diagram of a method 1000 for providing or fabricating a metallization portion. In some implementations, the method 1000 of FIG. 10 may be used to provide or fabricate the metallization portion(s) of the disclosure. For example, the method 1000 of FIG. 10 may be used to fabricate the metallization portion 107.

It should be noted that the method 1000 of FIG. 10 may combine one or more processes in order to simplify and/or clarify the method for providing or fabricating a metallization portion. In some implementations, the order of the processes may be changed or modified.

The method provides (at 1005) a carrier with a seed layer. Stage 1 of FIG. 9A, illustrates and describes an example of a state after a carrier 900 is provided. A seed layer 901 may be located over the carrier 900. The carrier 900 may be replaced with other components and/or materials.

The method forms and patterns (at 1010) a plurality of interconnects. Stage 2 of FIG. 9A, illustrates and describes an example of a state after a plurality of interconnects 912 are formed. The interconnects 912 may be located over the seed layer 901. A lithography process, a plating process, a strip process and/or an etching process may be used to form the plurality of interconnects 912. The interconnects 912 may represent at least some of the interconnects from the plurality of metallization interconnects 123.

The method forms (at 1010) a dielectric layer. Stage 3 of FIG. 9A, illustrates and describes an example of a state after a dielectric layer 910 is formed over the carrier 900, the seed layer 901 and the plurality of interconnects 912. A deposition and/or lamination process may be used to form the dielectric layer 910. The dielectric layer 910 may include prepreg and/or polyimide. The dielectric layer 910 may include a photo-imageable dielectric. However, different implementations may use different materials for the dielectric layer.

The method forms (at 1020) a plurality of interconnects. Forming a plurality of interconnects may including forming a plurality of cavities in a dielectric layer and a performing a plating process. Stage 4 of FIG. 9A, illustrates and describes an example of a state after a plurality of cavities 913 is formed in the dielectric layer 910. The plurality of cavities 913 may be formed using an etching process (e.g., photo etching process), a laser process, an exposure process and/or a development process.

Stage 5 of FIG. 9A, illustrates and describes an example of a state after interconnects 922 are formed in and over the dielectric layer 910, including in and over the plurality of cavities 913. For example, a via, pad and/or traces may be formed. A lithography process, a plating process, a strip process and/or an etching process may be used to form the interconnects.

The method forms (at 1025) another dielectric layer. Stage 6 of FIG. 9B, illustrates and describes an example of a state after a dielectric layer 920 is formed over the dielectric layer 910 and the plurality of interconnects 922. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

The method forms (at 1030) a plurality of interconnects. Forming a plurality of interconnects may including forming a plurality of cavities in a dielectric layer and a performing a plating process. Stage 7 of FIG. 9B, illustrates and describes an example of a state after a plurality of cavities 923 is formed in the dielectric layer 940. The dielectric layer 940 may represent the dielectric layer 910 and/or the dielectric layer 920. The plurality of cavities 923 may be formed using an etching process (e.g., photo etching process), a laser process, an exposure process and/or a development process.

Stage 8 of FIG. 9B, illustrates and describes an example of a state after interconnects 932 are formed in and over the dielectric layer 940, including in and over the plurality of cavities 923. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

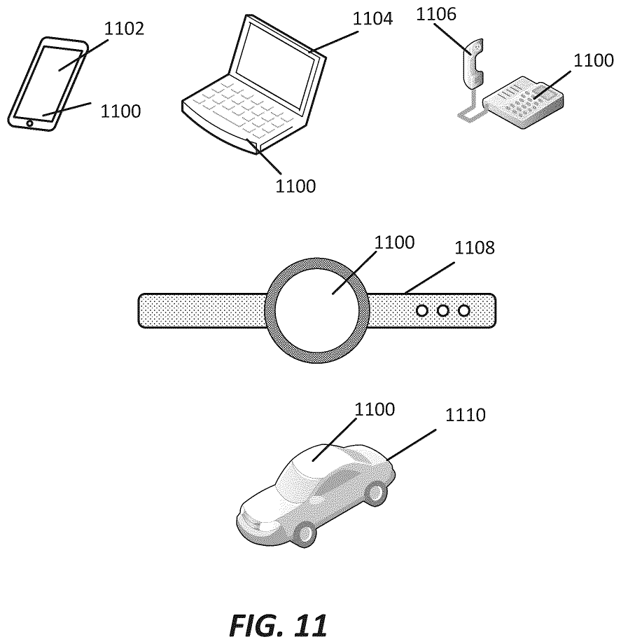

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5B, 6, 7A-7B, 8, 9A-9B, and 10-11 may be rearranged and/or combined into a single component, process, feature or function or embodied in several components, processes, or functions. Additional elements, components, processes, and/or functions may also be added without departing from the disclosure. It should also be noted FIGS. 1-4, 5A-5B, 6, 7A-7B, 8, 9A-9B, and 10-11 and its corresponding description in the present disclosure is not limited to dies and/or ICs. In some implementations, FIGS. 1-4, 5A-5B, 6, 7A-7B, 8, 9A-9B, and 10-11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate; and a passive device coupled to the substrate through at least a first plurality of solder interconnects, the passive device comprising a trench capacitor device; an encapsulation layer; and a metallization portion coupled to the trench capacitor device and the encapsulation layer.

Aspect 2: The package of aspect 1, wherein the metallization portion comprises: at least one dielectric layer; and a plurality of metallization interconnects.

Aspect 3: The package of aspect 2, wherein the plurality of metallization interconnects comprise at least one bar metallization interconnect.

Aspect 4: The package of aspect 2, wherein the plurality of metallization interconnects comprises a plurality of bar metallization interconnects located along a periphery of the trench capacitor device.

Aspect 5: The package of aspect 4, wherein the plurality of bar metallization interconnects are configured to provide an electrical path for ground.

Aspect 6: The package of aspects 2 through 5, wherein the first plurality of solder interconnects are coupled to the plurality of metallization interconnects.

Aspect 7: The package of aspects 2 through 6, wherein the passive device is coupled to a first surface of the substrate through the first plurality of solder interconnects.

Aspect 8: The package of aspect 7, further comprising a second plurality of solder interconnects coupled to the first surface of the substrate.

Aspect 9: The package of aspect 8, wherein a region between an edge of the passive device and a nearest solder interconnect from the plurality of solder interconnects has a minimum spacing of about 280 micrometers.

Aspect 10: The package of aspect 8 through 9, further comprising an integrated device coupled to a second surface of the substrate through a third plurality of solder interconnects.

Aspect 11: The package of aspect 10, further comprising an underfill located between the integrated device and the first surface of the substrate.

Aspect 12: The package of aspect 11, wherein a region between the passive device and the first surface of the substrate is free of an underfill.

Aspect 13: The package of aspects 1 through 12, wherein the trench capacitor device comprises a die substrate; and a plurality of trench capacitors located at least partially in the die substrate.

Aspect 14: A passive device comprising a trench capacitor device; an encapsulation layer; and a metallization portion coupled to the trench capacitor device and the encapsulation layer.

Aspect 15: The passive device of aspect 14, wherein the metallization portion comprises at least one dielectric layer; and a plurality of metallization interconnects.

Aspect 16: The passive device of aspect 15, wherein the plurality of metallization interconnects comprise at least one bar metallization interconnect.

Aspect 17: The passive device of aspect 15, wherein the plurality of metallization interconnects comprises a plurality of bar metallization interconnects located along a periphery of the trench capacitor device.

Aspect 18: The passive device of aspects 14 through 17, wherein the trench capacitor device comprises a die substrate; and a plurality of trench capacitors located at least partially in the die substrate.

Aspect 19: The passive device of aspect 18, wherein the encapsulation layer is coupled to the die substrate and the metallization portion.

Aspect 20: The passive device of aspects 14 through 19, wherein the metallization portion is coupled to a front side of the trench capacitor device.

Aspect 21: A device comprising the passive device of aspects 11 through 20, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: A device comprising the package of aspects 1 through 10, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate; and
a passive device coupled to the substrate through at least a first plurality of solder interconnects, the passive device comprising:
a trench capacitor device;
an encapsulation layer; and
a metallization portion coupled to the trench capacitor device and the encapsulation layer.

2. The package of claim 1, wherein the metallization portion comprises:
at least one dielectric layer; and
a plurality of metallization interconnects.

3. The package of claim 2, wherein the plurality of metallization interconnects comprise at least one bar metallization interconnect.

4. The package of claim 2, wherein the plurality of metallization interconnects comprises a plurality of bar metallization interconnects located along a periphery of the trench capacitor device.

5. The package of claim 4, wherein the plurality of bar metallization interconnects are configured to provide an electrical path for ground.

6. The package of claim 2, wherein the first plurality of solder interconnects are coupled to the plurality of metallization interconnects.

7. The package of claim 2, wherein the passive device is coupled to a first surface of the substrate through the first plurality of solder interconnects.

8. The package of claim 7, further comprising a second plurality of solder interconnects coupled to the first surface of the substrate.

9. The package of claim 8, wherein a region between an edge of the passive device and a nearest solder interconnect from the plurality of solder interconnects has a minimum spacing of about 280 micrometers.

10. The package of claim 8, further comprising an integrated device coupled to a second surface of the substrate through a third plurality of solder interconnects.

11. The package of claim 10, further comprising an underfill located between the integrated device and the first surface of the substrate.

12. The package of claim 11, wherein a region between the passive device and the first surface of the substrate is free of an underfill.

13. The package of claim 1, wherein the trench capacitor device comprises:
a die substrate; and
a plurality of trench capacitors located at least partially in the die substrate.

14. A passive device comprising:
a trench capacitor device;
an encapsulation layer; and
a metallization portion coupled to the trench capacitor device and the encapsulation layer.

15. The passive device of claim 14, wherein the metallization portion comprises:
at least one dielectric layer; and
a plurality of metallization interconnects.

16. The passive device of claim 15, wherein the plurality of metallization interconnects comprise at least one bar metallization interconnect.

17. The passive device of claim 15, wherein the plurality of metallization interconnects comprises a plurality of bar metallization interconnects located along a periphery of the trench capacitor device.

18. The passive device of claim 14, wherein the trench capacitor device comprises:
a die substrate; and
a plurality of trench capacitors located at least partially in the die substrate.

19. The passive device of claim 18, wherein the encapsulation layer is coupled to the die substrate and the metallization portion.

20. The passive device of claim 14, wherein the metallization portion is coupled to a front side of the trench capacitor device.
